(19) United States
(12) Patent Application Publication
(10) Pub. No.: US 2026/0242951 A1
(43) Pub. Date: Aug. 20, 2026

(54) SUBSTRATE SUSCEPTOR ASSEMBLY

(71) Applicant: ASM IP Holding B.V., Almere (NL)

(72) Inventors: Rajmohan Muthaiah, Chandler, AZ (US); Ananthkrishna Jupudi, Anthem, AZ (US); Kalayarasan Seranthian, Tempe, AZ (US); Arun Thottappayil, Chandler, AZ (US); Ruchik Jayeskumar Bhatt, Chandler, AZ (US); Avinash Shantaram, Scottsdale, AZ (US)

(21) Appl. No.: 19/536,543

(22) Filed: Feb. 11, 2026

Related U.S. Application Data
(60) Provisional application No. 63/758,507, filed on Feb. 14, 2025.

(51) Int. Cl. C23C 16/458; H01J 37/32

(52) U.S. Cl. CPC C23C 16/4586; H01J 37/3244

(57) ABSTRACT

Susceptor assemblies that can be used for a variety of applications are disclosed. Exemplary susceptor assemblies include a base plate having one or more cooling channels formed therein, an electrical isolation plate overlying the base plate, a heater plate overlying the electrical isolation plate, and a top plate overlying the heater plate. The heater plate can be configured as a plasma power electrode.

### CROSS-REFERENCE TO RELATED APPLICATIONS

This application is a nonprovisional of, and claims priority to and the benefit of, U.S. Provisional Patent Application No. 63/758,507, filed Feb. 14, 2025 and entitled “SUBSTRATE SUSCEPTOR ASSEMBLY,” which is hereby incorporated by reference herein.

### FIELD OF INVENTION

The present disclosure generally relates to gas-phase reactor systems and components thereof. More particularly, the disclosure relates to susceptor assemblies for supporting a substrate and providing various functions during processing of the substrate in a gas-phase reactor.

### BACKGROUND OF THE DISCLOSURE

Gas-phase reactors can be used for a variety of applications, such as chemical vapor deposition (CVD), plasma-enhanced CVD (PECVD), physical vapor deposition (PVD), atomic layer deposition (ALD), plasma-enhanced ALD (PEALD), degassing, substrate precleaning, etch processes, and the like. For example, gas-phase reactors can be used to deposit material, etch layers, and/or clean material on a substrate to form electronic devices, such as semiconductor devices, flat panel display devices, photovoltaic devices, microelectromechanical systems (MEMS), and the like.

A typical gas-phase reactor system includes one or more reactors, each reactor including a reaction chamber, a susceptor assembly within the reaction chamber, and one or more gas sources fluidly coupled to the reaction chamber. Typically, a design or configuration of a susceptor assembly used to support a substrate depends on a type of processing. For example, a susceptor assembly used during a preclean and/or degas process is typically configured differently than a susceptor assembly used in a plasma-enhanced process. Similarly, a configuration of a susceptor assembly used in a CVD process may differ from a configuration of a susceptor assembly used in a PVD process. While such dedicated susceptor design configurations work well for many applications, use of such dedicated susceptor designs may be relatively expensive and/or time consuming when, for example, reconfiguring gas-phase reactors for different processes. In addition, spare parts storage and/or parts replacement may be relatively expensive when using specifically designed susceptors. Accordingly, improved susceptor designs that can be used for a variety of applications are desired.

Any discussion of problems and solutions described in this section has been included in this disclosure solely for the purposes of providing a context for the present disclosure and should not be taken as an admission that any or all of the discussion is prior art or was known at the time the invention was made.

### SUMMARY OF THE DISCLOSURE

Various embodiments of the present disclosure relate to susceptor assemblies and components thereof suitable for use in gas-phase reactor apparatus and systems, as well as to reactors systems including the susceptor assemblies. Exemplary susceptor assemblies can be used during a variety of gas-phase processes and are relatively easy and inexpensive to maintain. While the ways in which various embodiments of the present disclosure address drawbacks of prior susceptor assemblies are discussed in more detail below, in general, various embodiments of the disclosure provide improved susceptor assemblies that include various electrodes, heaters, and cooling channels, such that the susceptors be used in different processes, such as plasma enhanced processes (e.g., PEALD or PECVD), PVD, pre-clean processes, degas processes, etch processes or the like.

In accordance with at least one embodiment of the disclosure, a susceptor assembly includes a base plate having one or more cooling channels formed therein, an electrical isolation plate overlying the base plate, the electrical isolation plate, a heater plate overlying the electrical isolation plate, and a top plate overlying the heater plate. In accordance with examples of these embodiments, the base plate and the electrical isolation plate have an opening through the respective plates to allow for a conduit and various connectors, wires, thermocouples, and/or other devices, which can be inserted therein, and which can form part of the assemblies. In accordance with further examples, the assembly can include a bellows assembly. The bellows assembly can be coupled to the base plate and/or a ground plate. In accordance with yet further examples, the susceptor assembly includes a conductive tube electrically coupled to the heater plate. The conductive tube can be disposed within a base plate opening and within an isolation plate opening. The susceptor assembly can further include a plasma power source electrically coupled to the conductive tube. The conductive tube can be or include a metal conduit and a coating of silver thereon. As set forth in more detail below, various plates can be bonded to one or more adjacent plates. By way of examples, the plates can be bonded together using a metal, such as a post-transition metal, such as indium or the like. The top plate can include electrostatic chucking electrodes. At least one electrostatic chucking electrode of the electrostatic electrodes can be electrically coupled to an electrostatic chucking power source. The electrostatic chucking power source can be configured to apply a first electrostatic bias to the electrostatic electrodes to chuck a substrate and to apply a second, opposite electrostatic bias to the electrostatic electrodes to dechuck the substrate. The heater plate be configured as or function as a plasma power electrode. Additionally or alternatively, the heater plate can include one or more heaters at least partially embedded therein. The top plate can be removably attached to the heater plate. In accordance with further examples, the heater plate can include a heater plate opening therethrough. The heater plate opening can be fluidly coupled to a cooling gas source to provide a cooling gas proximate the top plate.

In accordance with additional embodiments of the disclosure, a reactor system includes one or more reactors, wherein at least one of the one or more reactors includes a susceptor assembly as described herein. The reactor system can additionally include one or more gas sources coupled to the one or more reactors, a vacuum source, and a controller.

These and other embodiments will become readily apparent to those skilled in the art from the following detailed description of certain embodiments having reference to the attached figures. The invention is not limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a reactor system in accordance with at least one embodiment of the disclosure.

FIG. 2 illustrates an exploded view of a susceptor assembly in accordance with examples of the disclosure.

FIG. 3 illustrates a cooling channel in a base plate in accordance with examples of the disclosure.

FIG. 4 illustrates an electrostatic chucking electrode pattern in accordance with examples of the disclosure.

FIG. 5 illustrates another susceptor assembly in accordance with examples of the disclosure.

FIG. 6 illustrates a cross-sectional view of a susceptor assembly in accordance with examples of the disclosure.

FIG. 7 illustrates a top view of a susceptor assembly in accordance with examples of the disclosure.

FIG. 8 illustrates a bottom view of the susceptor assembly of FIG. 5 in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to susceptor assemblies suitable for use with gas-phase reactor systems and to reactor systems including the susceptor assemblies. The susceptor assemblies and systems as described herein can be used to process substrates, such as semiconductor wafers, to form, for example, electronic devices.

Exemplary susceptor assemblies described herein can be used in a variety of processes, such as CVD, ALD, plasma-enhanced processes, etch processes, clean processes, PVD, and the like. In other words, the same susceptor can be used for, for example, any combination of such processes or similar processes. This allows for relatively rapid and inexpensive changes to a reactor configuration and can allow for relatively less expensive storage of spare parts.

As used herein, the term substrate may refer to any underlying material or materials, including and/or upon which material can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can include various gaps, such as recesses, vias, spaces between lines, trenches, and the like formed on the surface of the substrate.

In this disclosure, gas can include material that is a gas at normal temperature and pressure (NTP), a vaporized solid and/or a vaporized liquid, and can be constituted by a single gas or a mixture of gases, depending on the context. A gas other than a process gas, i.e., a gas introduced without passing through a gas distribution assembly, other gas distribution device, or the like, can be used for, e.g., sealing the reaction space, and can include a seal gas, such as a rare gas.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like, in some embodiments. For example, the term about can refer to +/−20, 10, 5, 2, or 1 percent of a value. Further, in this disclosure, the terms including, comprising, constituted by and having and their equivalents can refer independently to typically or broadly comprising, consisting essentially of, or consisting of in some embodiments. In accordance with aspects of the disclosure, any defined meanings of terms do not necessarily exclude ordinary and customary meanings of the terms.

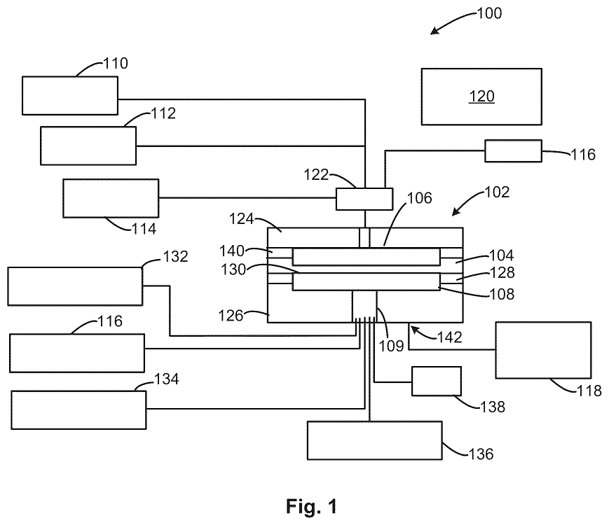

Turning now to the figures, FIG. 1 illustrates a reactor system 100 in accordance with at least one embodiment of the disclosure. Reactor system 100 includes a reactor 102 including a reaction chamber 104, a gas distribution device 106, a susceptor assembly 108, gas sources 110-116, an exhaust source 118, a controller 120, a heater power source 132, a plasma power source 134, a cooling fluid source 136, and an electrostatic chucking power source 138. Although illustrated with one reactor 102/reaction chamber 104, reactor system 100 can include any suitable number of reaction chambers 104 and can optionally include one or more substrate handling systems.

Reactor 102 can be configured as a CVD reactor, a cyclical deposition process reactor (e.g., a cyclical CVD reactor), an ALD reactor, a PEALD reactor, a PVD reactor, a cleaning chamber, a degas chamber, or the like, any of which may include plasma apparatus, such as direct and/or remote plasma apparatus. Reaction chamber 104 can be formed of suitable material, such as quartz, metal, or the like, and can be configured to retain one or more substrates for processing. As described in more detail below, susceptor assembly 108 can be used in any such reactor configurations. Susceptor assembly 108 allows for reactor 102 to be configured and easily reconfigured as desired (e.g., as a plasma or non-plasma reactor, with electrostatic chucking or not, with cooling or not, and the like).

Reaction chamber 104 includes an upper chamber portion 124 and a lower chamber portion 126. Upper chamber portion 124 and lower chamber portion 126 can be separated by an isolation plate 128. Additionally or alternatively, upper chamber portion 124 can be above a top surface 130 of susceptor assembly 108 and/or lower chamber portion 126 can be below top surface 130 of susceptor assembly 108.

Gas distribution device 106 provides gas from one or more gas sources 110-114 to upper chamber portion 124. By way of examples, gas distribution device 106 can be or include an assembly that includes a showerhead device.

Susceptor assembly 108 can support a substrate to be processed and can be positioned below gas distribution device 106. Susceptor assembly 108 can be coupled to moveable shaft 109, which can move susceptor assembly 108 from a processing position to a load/unload position, as described below.

Gas sources 110-116 can each include a vessel and a reactant, precursor, or cooling gas stored within the respective vessel. By way of example, first gas source 110 can include a vessel and a carrier gas; second gas source 112 can include a vessel and a precursor for a deposition or etch process; third gas source 114 can include a vessel and a reactant; and fourth gas source 116 can include a vessel and a cooling gas, such as argon, helium, mixtures of hydrogen and helium, neon, or the like.

Any of gas sources 110-116 can be coupled to a remote plasma unit (RPU) 122 and/or can bypass RPU 122 and be coupled to gas distribution device 106 or upper chamber portion 124. Further, although illustrated with four gas sources 110-116, exemplary systems can include any suitable number of gas sources (e.g., four or more) coupled to reaction chamber 104.

Exhaust source 118 can include, for example, one or more vacuum sources. Exemplary vacuum sources include one or more dry vacuum pumps and/or one or more turbomolecular pumps.

Controller 120 can be configured to perform various functions and/or steps as described herein. Controller 120 can include one or more microprocessors, memory elements, and/or switching elements to perform the various functions. Although illustrated as a single unit, controller 120 can alternatively comprise multiple devices. By way of examples, controller 120 can be used to control gas flow from one or more gas sources 110-114 to reaction chamber 104 during a process; gas flow from cooling gas source 116, a portion of susceptor assembly 108, or the like. Additional functions of controller 120 are discussed in more detail below.

Isolation plate 128 can be used to control a flow of gas between upper chamber portion 124 and lower chamber portion 126. Reactor 102 can also include one or more exhaust ports 140 (above) and 142 (below) top surface 130.

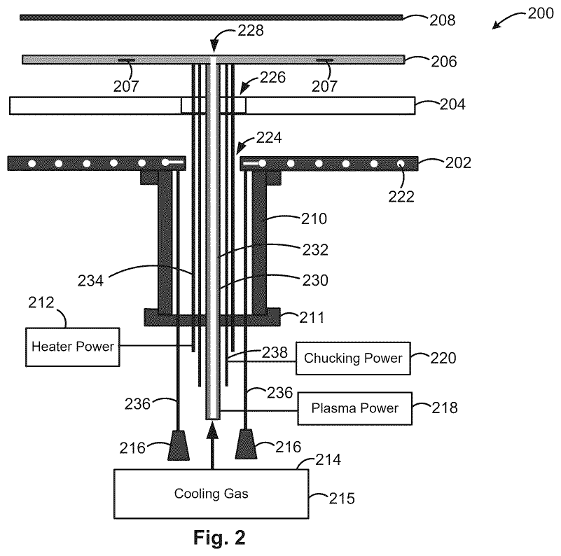

FIG. 2 illustrates an exploded view of a susceptor assembly 200 in accordance with examples of the disclosure. Susceptor assembly 200 can be used as susceptor assembly 108—e.g., within reactor system 100.

In the illustrated example, susceptor assembly 200 includes a base plate 202, an electrical isolation plate 204, a heater plate 206, and a top plate 208. Susceptor assembly 200 further includes a bellows assembly 210 and a ground plate 211. As illustrated, susceptor assembly 200 can also include one or more of a heater power source 212, a cooling gas source 214, a cooling fluid source 216, a plasma power source 218, and an electrostatic chucking power source 220.

Base plate 202 can be formed of any suitable material, such as heat conductive material. For example, base plate 202 can suitably include or be formed of a metal, such as aluminum, stainless steel, copper or the like. Base plate 202 can include one or more cooling channels 222 formed therein, such that a cooling fluid, such as water, glycol mixed water, or the like, from cooling fluid source 216 can flow through the one or more cooling channels 222 to cool susceptor assembly 200. Base plate 202 includes a base plate opening 224, through which various conduits and/or wires can flow, as discussed in more detail below. A diameter or similar cross-sectional dimension of base plate 202 can be from about 300 to about 400 mm. A height of base plate 202 can be between about 5 and about 25 mm.

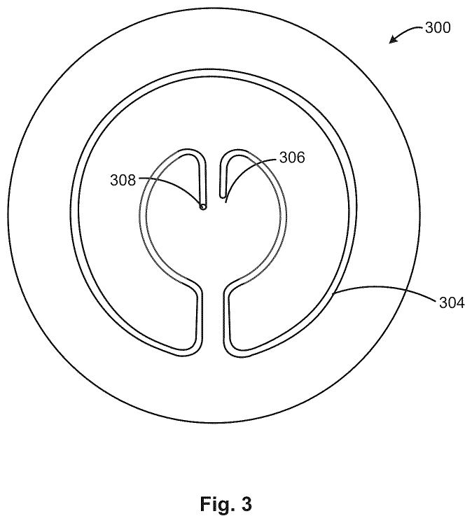

FIG. 3 illustrates a cross-sectional view of an exemplary base plate 300, suitable for use as base plate 202. In this example, base plate 300 includes a single cooling channel 304 that includes an inlet 306 and an outlet 308.

Electrical isolation plate 204 is positioned overlying base plate 202. Electrical isolation plate 204 can be formed of any suitable electrically isolating and thermally conductive material. By way of examples, electrical isolation plate 204 can include or be formed of a ceramic material. Exemplary suitable ceramic materials include ceramic materials having a thermal conductivity above 30 W/m.K. Such materials include alumina, composites of alumina, aluminum silicon carbide, aluminum nitride, or the like.

In accordance with examples of the disclosure, electrical isolation plate 204 is bonded to base plate 202. Electrical isolation plate 204 can be bonded to base plate 202 using a heat conductive bond, such as indium, polymer, aluminum, or the like. The bonding allows for thermal conductivity between plates and provides vacuum integrity between the plates.

Electrical isolation plate 204 includes an isolation plate opening 226 therethrough. Similar to base plate opening 224, isolation plate opening 226 can be configured to receive various conductors and/or conduits and/or other peripheral devices therein. However, isolation plate opening 226 may be smaller than base plate opening 224, because isolation plate opening 226 need not receive a conduit for a cooling fluid that is received within base plate opening 224. In some cases, a diameter or other similar cross-sectional dimension of electrical isolation plate 204 can be the same or similar to a diameter or other similar cross-sectional dimension of base plate 202. A height of electrical isolation plate 204 can be between about 5 mm and about 25 mm.

Heater plate 206 can be formed of any suitable heat conductive material. By way of examples, heater plate 206 can be formed of a metal or metallic material, such as aluminum, stainless steel, or the like, or ceramic material, such as alumina, composites of alumina, or the like.

In accordance with examples of the disclosure, heater plate 206 includes one or more (e.g., resistive) heaters 207 at least partially embedded therein or (e.g., within trenches on a backside) thereon. Heaters 207 can be formed of, for example, stainless steel, other grades of steel, tungsten, or the like. In accordance with examples of the disclosure, heater plate 206 will also function as a plasma power electrode.

Heater plate 206 overlies electrical isolation plate 204 and can be (e.g., directly) bonded to electrical isolation plate 204. The bonding can be done using techniques and/or (e.g., thermally conductive) materials described herein.

Heater plate 206 includes a heater plate opening 228 therethrough. Heater plate opening 228 can be configured to receive various conduits and/or other peripheral devices therein. Heater plate opening 228 may be smaller than isolation plate opening 226, because heater plate opening 228 need not receive various components, such as electrical conductors that are coupled to heater plate 206. In some cases, a diameter or other similar cross-sectional dimension of heater plate 206 can be the same or smaller than a diameter or other similar cross-sectional dimension of electrical isolation plate 204. In accordance with examples of the disclosure, heater plate opening 228 is fluidly coupled to cooling gas source 214 to provide a cooling fluid proximate (e.g., to the backside of) top plate 208.

Top plate 208 can similarly be formed of a heat-conductive ceramic material. Exemplary top plate materials include ceramics, such as alumina, aluminum nitride, or the like.

Top plate 208 is overlying heater plate 206. Top plate 208 can be bonded to heater plate 206 using bonding techniques and/or materials described herein. Alternatively, top plate 208 can be removably (e.g., mechanically) coupled to heater plate 206.

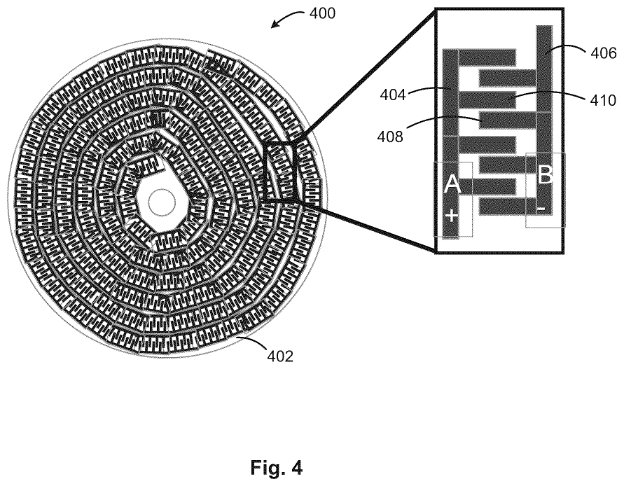

FIG. 4 illustrates a top view of a top plate 400 suitable for use as top plate 208. Top plate 400 includes a top surface 402 having electrostatic chucking electrodes 404 and 406 thereon. As illustrated, electrostatic chucking electrodes 404 and 406 or at least portions thereof can be a substantially constant distance apart. Further, electrostatic chucking electrodes 404 and 406 can form a substantial spiral over top surface 402. Yet further, as illustrated, electrostatic chucking electrodes 404 and 406 can include interdigitated protrusions or fingers 408 and 410. Electrostatic chucking electrodes 404 and 406 can be formed of any suitable material, such as, for example, tungsten, grades of steel that are chromium rich, molybdenum, or the like.

With reference again to FIG. 2, heater power source 212 can include any suitable power source. For example, heater power source 212 can include a current power source. Heater power source 212 can include a controller or can be controlled by controller 120. As illustrated, heater power source 212 can be electrically coupled to one or more heaters 207 using conductive wires 234 within openings 224 and 226.

Cooling gas source 214 can include a vessel 215 and a cooling gas therein. Exemplary cooling gases include inert gases like argon, helium, mixtures of hydrogen and helium, neon, or the like. Cooling gas from cooling gas source 214 can be provided proximate (e.g., to a back surface of) top plate 208—e.g., through a conduit 230 and opening 228.

Cooling fluid source 216 can include a cooling fluid, such as water, glycol mixed water, or the like. Cooling fluid source 216 can include vessel or can be sourced from a continuous supply. Cooling fluid source 216 can be fluidly coupled to the one or more cooling channels 222 to supply the cooling fluid to one or more cooling channels 222, which can be the same or similar to channel 304. Cooling fluid from cooling fluid source 216 can be supplied to cooling fluid channels via conduits (e.g., pipes) 236. In some cases, one or more cooling channels 222 can form one or more circulation loops that can form one or more cooling regions within base plate 202.

Plasma power source 218 can be configured to provide suitable plasma power to heater plate 206, which can function as a plasma power electrode. As illustrated, plasma power source 218 can be electrically coupled to heater plate 206 and to a conductive tube 232. Conductive tube 232 can be formed of any suitable material, such as, for example, metal conduit (e.g., copper pipe) having a coating of silver thereon. Conductive tube 232 can be disposed within base plate opening 224 and within isolation plate opening 226 and bellows assembly 210.

Bellows assembly 210 can be configured to provide a substantial gas seal between base plate 202 and ground plate 211. Bellows assembly 210 can be coupled to base plate 202 using mechanical fasteners, such as bolts or the like. Bellows assembly 210 can similarly be mechanically fastened to ground plate 211, such that bellows assembly 210 is electrically coupled to ground plate 211.

Electrostatic chucking power source 220 can be or include any suitable power source. By way of example, electrostatic chucking power source 220 is or includes a DC voltage power source with polarity switching. In accordance with examples of the disclosure, at least one electrostatic chucking electrode (e.g., electrostatic chucking electrode 404 and/or 406) of the electrostatic electrodes is electrically coupled to electrostatic chucking power source 220—e.g., using wires 238. In some cases, electrostatic chucking power source 220 is configured to apply a first electrostatic bias to the electrostatic electrodes to chuck a substrate and to apply a second, opposite electrostatic bias to the electrostatic electrodes to dechuck the substrate.

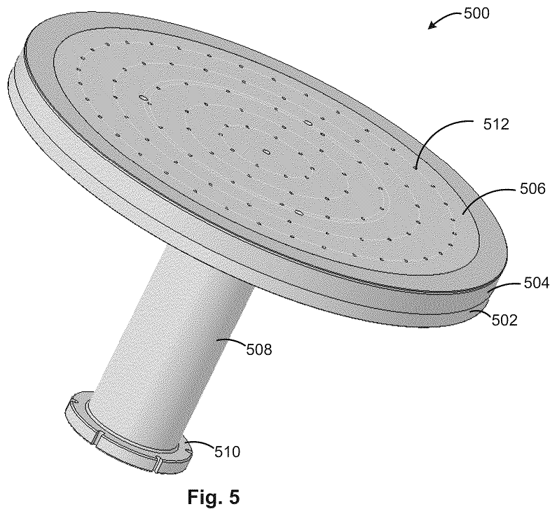

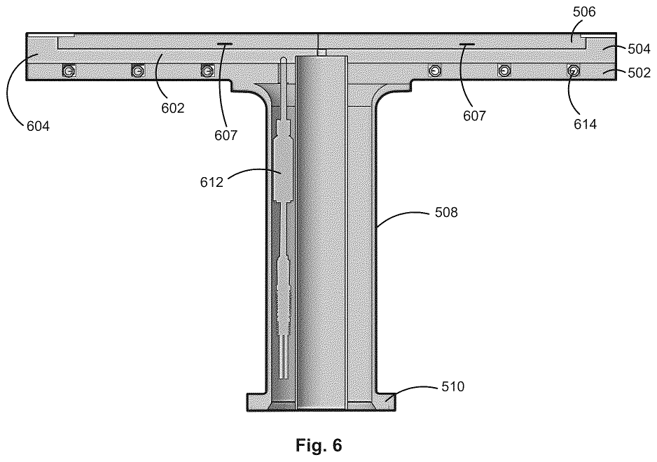

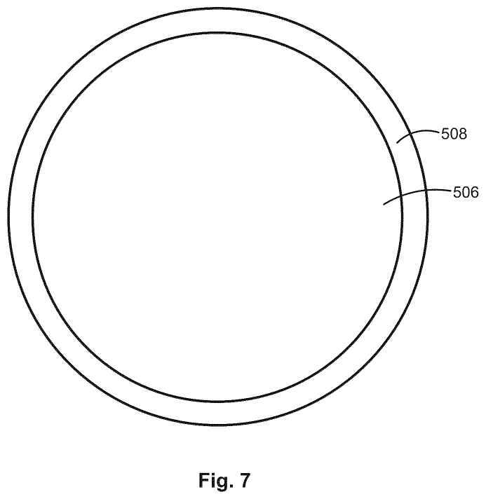

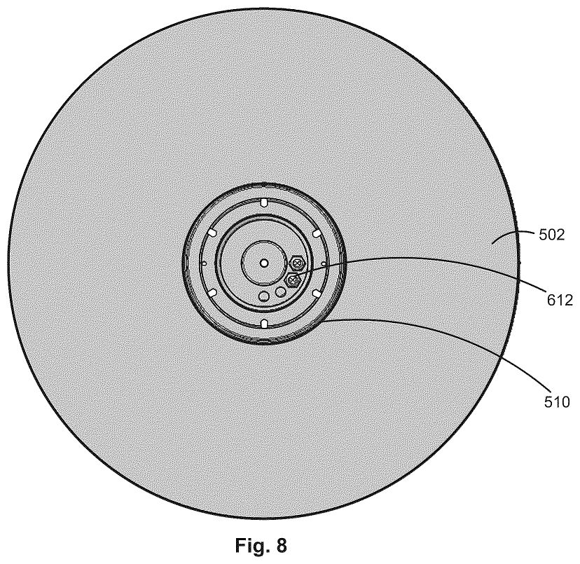

FIG. 5 to FIG. 8 illustrate another susceptor assembly 500 in accordance with examples of the disclosure. Susceptor assembly 500 includes a base plate 502, an electrical isolation plate 504, and a heater plate 506. Susceptor assembly 500 also includes a bellows assembly 508 and a ground plate 510. Susceptor assembly 500 can also include one or more of a heater power source, a cooling gas source, a cooling fluid source, a plasma power source, and an electrostatic chucking power source, such as heater power source 212, a cooling gas source 214, a cooling fluid source 216, a plasma power source 218, and an electrostatic chucking power source 220, and corresponding lines and conduits described above in connection with FIG. 2. In the illustrated example, susceptor assembly 500 also includes one or more thermocouples 612. Susceptor assembly 200 can similarly include one or more thermocouples and/or a top plate as described above in connection with FIG. 2 and FIG. 4.

Base plate 502, bellows assembly 508, and ground plate 510 can be the same or similar to base plate 202, bellows assembly 210, and ground plate 211 described above in connection with FIG. 2. For example, base plate 502 can include cooling channels 614, which can be the same or similar to cooling channels 222, which can suitably be fluidly coupled to cooling fluid source 216 via lines, such as conduits 236.

Electrical isolation plate 504 can be formed of the same materials as electrical isolation plate 204 and can be similar to electrical isolation plate 204, except, electrical isolation plate 504 includes a central portion 602 and a peripheral portion 604. Central portion 602 can have a diameter of about 300 to about 325 mm. An outer diameter of peripheral portion 604 can be about 330 to about 400 mm; the inner diameter of peripheral portion 604 can coincide with the diameter of central portion 602. A height of central portion 602 can be about 5 to about 15 mm. A height of peripheral portion 604 can be about 5 to about 25 mm.

Heater plate 506 can be similar to heater plate 206 described above. For example, heater plate 506 can include one or more (e.g., resistive) heaters 607 at least partially embedded therein or (e.g., within trenches on a backside) thereon. Heaters 607 can be the same or similar to heaters 207 described above. In addition, heater plate 506 can function as a plasma power electrode. As illustrated, heater plate 506 can include conductive bumps 512. Conductive bumps 512 can be formed of any suitable conductive material, such as conductive materials noted herein. A diameter of the conductive bumps 512 can be, for example, about 1.5 mm; a height of conductive bumps can be about 0.5 mm.

As noted above, susceptor assembly 500 can include a top plate, such as top plate 208 or 400 described above. The top place can be placed on conductive bumps 512.

As noted above, example embodiments of the disclosure described above do not limit the scope of the invention, since these embodiments are merely examples of the embodiments of the invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A susceptor assembly comprising:
a base plate having one or more cooling channels formed therein;
an electrical isolation plate overlying the base plate, the electrical isolation plate comprising an isolation plate opening therethrough;
a heater plate overlying the electrical isolation plate; and
a top plate overlying the heater plate.

2. The susceptor assembly of claim 1, further comprising a cooling fluid source fluidly coupled to the one or more cooling channels.

3. The susceptor assembly of claim 1, wherein the base plate is coupled to a bellows assembly.

4. The susceptor assembly of claim 3, wherein the bellows assembly is electrically coupled to a ground plate.

5. The susceptor assembly of claim 1, further comprising:
a conductive tube disposed within the base plate opening and within the isolation plate opening; and
a plasma power source electrically coupled to the conductive tube.

6. The susceptor assembly of claim 5, wherein the conductive tube comprises a metal conduit and a coating of silver thereon.

7. The susceptor assembly of claim 1, wherein the electrical isolation plate is bonded to the base plate using one or more of indium, a polymer, or aluminum.

8. The susceptor assembly of claim 1, wherein the heater plate is bonded to the electrical isolation plate using one or more of indium, a polymer, or aluminum.

9. The susceptor assembly of claim 1, wherein the top plate is bonded to the heater plate.

10. The susceptor assembly of claim 1, wherein the top plate comprises electrostatic chucking electrodes, and wherein at least one electrostatic chucking electrode of the electrostatic electrodes is electrically coupled to an electrostatic chucking power source.

11. The susceptor assembly of claim 10, wherein the electrostatic chucking power source is configured to apply a first electrostatic bias to the electrostatic electrodes to chuck a substrate and to apply a second, opposite electrostatic bias to the electrostatic electrodes to dechuck the substrate.

12. The susceptor assembly of claim 1, wherein the heater plate is configured as a plasma power electrode.

13. The susceptor assembly of claim 1, wherein the heater plate comprises one or more heaters embedded therein.

14. The susceptor assembly of claim 1, wherein the electrical isolation plate comprises ceramic material.

15. The susceptor assembly of claim 14, wherein the ceramic material is selected from one or more of alumina, aluminum silicon carbide, or aluminum nitride.

16. The susceptor assembly of claim 1, wherein the base plate comprises a metal.

17. The susceptor assembly of claim 1, wherein the top plate is removably attached to the heater plate.

18. The susceptor assembly of claim 1, wherein the heater plate comprises a heater plate opening therethrough.

19. The susceptor assembly of claim 18, wherein the heater plate opening is fluidly coupled to a cooling fluid source to provide a cooling fluid proximate the top plate.

20. A reactor system comprising:
a reactor comprising a reaction chamber;
the susceptor assembly of claim 1 within the reactor; and
a vacuum source coupled to the reaction chamber.
